(19) United States
(12) Patent Application Publication
(10) Pub. No.: US 2014/0002204 A1
(43) Pub. Date: Jan. 2, 2014

(54) DIGITALLY CONTROLLED OSCILLATOR HAVING IMPROVED LINEARITY

(71) Applicant: SAMSUNG ELECTRO-MECHANICS CO., LTD., Suwon (KR)

(72) Inventors: Yoo Hwan KIM, Gyunggi-do (KR); Gyu Suck KIM, Gyunggi-do (KR); Hyun Hwan YOO, Gyunggi-do (KR); Yoo Sam NA, Gyunggi-do (KR)

(73) Assignee: SAMSUNG ELECTRO-MECHANICS CO., LTD., Suwon (KR)

(21) Appl. No.: 13/645,153

(22) Filed: Oct. 4, 2012

(30) Foreign Application Priority Data
Jun. 29, 2012 (KR) 10-2012-0070464

(51) Int. Cl. H03B 28/00

(52) U.S. Cl. 331/167

(57) ABSTRACT

There is provided a digitally controlled oscillator. The digitally controlled oscillator includes a resonance circuit unit generating a resonance signal according to an equivalent capacitance formed by a parallel connection between a first capacitance varied depending on a digital control code and a second capacitance varied depending on an inverted digital control code generated by inverting the digital control code, and preset inductance; and an oscillation circuit unit providing negative resistance to the resonance circuit unit and forming oscillation conditions in the resonance circuit unit.

### CROSS-REFERENCE TO RELATED APPLICATIONS

This application claims the priority of Korean Patent Application No. 10-2012-0070464 filed on Jun. 29, 2012, in the Korean Intellectual Property Office, the disclosure of which is incorporated herein by reference.

### BACKGROUND OF THE INVENTION

1. Field of the Invention

The present invention relates to a digitally controlled oscillator having improved linearity, capable of being applied to a communications system and linearly controlling an oscillation frequency according to a digital control code.

2. Description of the Related Art

In general, frequency synthesizers applied to a communications system according to the related art includes an analog phase locked loop (PLL) and a digital phase locked loop.

Normally, an analog phase locked loop may be designed simultaneously with an analog circuit, separately from a digital library supplied in a manufacturing process. The analog phase locked loop consumes an excessive amount of time and may be relatively expensive, in accordance with a process change, and operational characteristics thereof may be deteriorated as a power supply is lowered.

On the other hand, an analog-controlled oscillator generates an oscillation frequency by using capacitance varied in a varactor diode according to an external voltage; however, a defect in an analog PLL as described above may result in deterioration of characteristics.

As a phase locked loop (PLL) is digitalized, an oscillator has also required a digitally controlled oscillator which generates an oscillation frequency linearly, according to a plurality of digital control signals. The digitally controlled oscillator is being researched and further developed to solve defects inherent in an analog-controlled oscillator.

A signal input to such a digitally controlled oscillator may be a plurality of digital signals, different from the analog-controlled oscillator. Normally, in a general analog-controlled oscillator, a current of a charge pump is converted into a voltage, the voltage is output as a corresponding voltage within a voltage range of 0V to 1.8V, and a capacitance of a varactor diode may be a first capacitance or a second capacitance, according to the output voltage.

However, in the case of a digitally controlled oscillator, a signal input thereto may be a plurality of digital control codes, so that a voltage input to the varactor diode may have a correspondingly a low level of voltage, e.g., 0V, or a high level voltage, e.g., Vdd. Accordingly, a characteristic curve of the varactor diode only has a first capacitance or a second capacitance.

That is, a digitally controlled oscillator may be discretely adjusted by a digital control code, and resolution of an oscillation frequency of the digitally controlled oscillator may be determined by a minimum or maximum value of the capacitance of the Varactor diode. In addition, noise characteristics of an all-digital PLL may depend on the resolution of the oscillation frequency.

For example, when a digitally controlled oscillator is designed to generate a frequency determined by inductance fixed, and capacitance varied, using a LC oscillator, a digitally controlled oscillator according to the related art may include a varactor diode and an inductor, and generate a desired frequency.

However, in a digitally controlled oscillator according to the related art using a varactor diode as described above, capacitance varied in the varactor diode according to a digital control code is not linear, but rather discrete, so that frequency resolution depending on a variance characteristic of capacitance provided from the varactor diode results in enlarging an interval between step frequencies.

Such capacitance resolution may not reduce an interval between step frequencies of a digitally controlled oscillator and may finally have a negative influence on phase noise and frequency locking.

Patent Document 1, related to a wide-bandwidth voltage controlled oscillator, does not disclose any technical contents for improving linearity by using capacitance varied depending on the digital control code and a capacitor varied depending on an inverted digital control code.

### RELATED ART DOCUMENTS

(Patent Document 1) Korean Patent Laid-Open Publication No. 10-2009-0027014

### SUMMARY OF THE INVENTION

An aspect of the present invention provides a digitally controlled oscillator having improved linearity, capable of being applied to a communications system and linearly controlling an oscillation frequency according to a digital control code.

According to an aspect of the present invention, there is provided a digitally controlled oscillator, including: a resonance circuit unit generating a resonance signal according to equivalent capacitance varied depending on a digital control code and preset inductance; and an oscillation circuit unit providing negative resistance to the resonance circuit unit and forming oscillation conditions in the resonance circuit unit, wherein the equivalent capacitance is a parallel summed capacitance of a first capacitance varied depending on the digital control code and a second capacitance varied depending on an inverted digital control code generated by inverting the digital control code.

The resonance circuit unit may include: a capacitance circuit unit providing the equivalent capacitance in order to generate the resonance signal; and an inductance circuit unit providing the preset inductance in order to generate the resonance signal.

The capacitance circuit unit may include: a first capacitor circuit unit providing the first capacitance varied depending on the digital control code; an inversion circuit unit providing the inverted digital control code by inverting the digital control code; and a second capacitor circuit unit connected to the first capacitor circuit unit in parallel to provide the second capacitance varied depending on the inverted digital control code.

The first capacitor circuit unit may include a first capacity element and a second capacity element connected to each other in series to provide the first capacitance determined according to the digital control code.

The second capacitor circuit unit may include a third capacity element and a fourth capacity element connected to each other in series to provide the second capacitance determined according to the inverted digital control code.

The inversion circuit unit may include an inverter inverting the digital control code.

The first capacitor circuit unit may have the first capacitance different from the second capacitance of the second capacitor circuit unit, with respec to the digital control code having the same logic level.

According to another aspect of the present invention, there is provided a digitally controlled oscillator, including: a resonance circuit unit generating a resonance signal according to equivalent capacitance varied depending on a digital control code and preset inductance; and an oscillation circuit unit providing negative resistance to the resonance circuit unit and forming oscillation conditions in the resonance circuit unit, wherein the resonance circuit unit includes: a capacitance circuit unit including first through n^{th} variable capacitance circuit units providing the equivalent capacitance; and an inductance circuit unit providing the inductance, the equivalent capacitance of the first through n^{th} variable capacitance circuit units being a parallel summed capacitance of the first capacitance varied depending on the digital control code and the second capacitance varied depending on an inverted digital control code generated by inverting the digital control code.

Respective first through n^{th} variable capacitance circuit units may provide equivalent capacitance varied depending on respective first through n^{th} digital control codes included in the digital control code.

The first variable capacitance circuit unit may include: a first capacitor circuit unit providing the first capacitance varied depending on the first digital control code; an inversion circuit unit providing the first inverted digital control code by inverting the first digital control code; and a second capacitor circuit unit connected to the first capacitor circuit unit in parallel to provide the second capacitance varied depending on the first inverted digital control code.

The first capacitor circuit unit may include a first capacity element and a second capacity element connected to each other in series to provide the first capacitance determined according to the first digital control code.

The second capacitor circuit unit may include a third capacity element and a fourth capacity element connected to each other in series to provide the second capacitance determined according to the first inverted digital control code.

The inversion circuit unit may include an inverter inverting the first digital control code.

The first capacitor circuit unit may have the first capacitance different from the second capacitance of the second capacitor circuit unit, with respect to the first digital control code having the same logic level.

The n^{th} variable capacitance circuit unit may include: a first capacitor circuit unit providing the first capacitance varied depending on the n^{th} digital control code; an inversion circuit unit providing the n^{th} inverted digital control code by inverting the n^{th} digital control code; and a second capacitor circuit unit connected to the first capacitor circuit unit in parallel to provide the second capacitance varied depending on the n^{th} inverted digital control code.

The first capacitor circuit unit may include a first capacity element and a second capacity element connected to each other in series to provide the first capacitance determined according to the n^{th} digital control code.

The second capacitor circuit unit may include a third capacity element and a fourth capacity element connected to each other in series to provide the second capacitance determined according to the n^{th} inverted digital control code.

The inversion circuit unit may include an inverter inverting the n^{th} digital control code.

The first capacitor circuit unit may have the first capacitance, different from the second capacitance of the second capacitor circuit unit, with respect to the n^{th} digital control code having the same logic level

### BRIEF DESCRIPTION OF THE DRAWINGS

The above and other objects, features and advantages of the present invention will be more clearly understood from the following detailed description taken in conjunction with the accompanying drawings, in which:

FIG. 1 is a block diagram of a digitally controlled oscillator according to a first embodiment of the present invention;

FIG. 2 is a block diagram of the digitally controlled oscillator according to a second embodiment of the present invention;

FIG. 3 is an explanation diagram of variable capacitance in a digital control mode and an analog control mode according to an embodiment of the present invention;

FIG. 4 is a conceptual graph for variable capacitance of a capacitance circuit unit according to an embodiment of the present invention; and

FIG. 5 is a graph for variable capacitance of a capacitance circuit unit according to the first embodiment of the present invention.

### DETAILED DESCRIPTION OF THE INVENTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

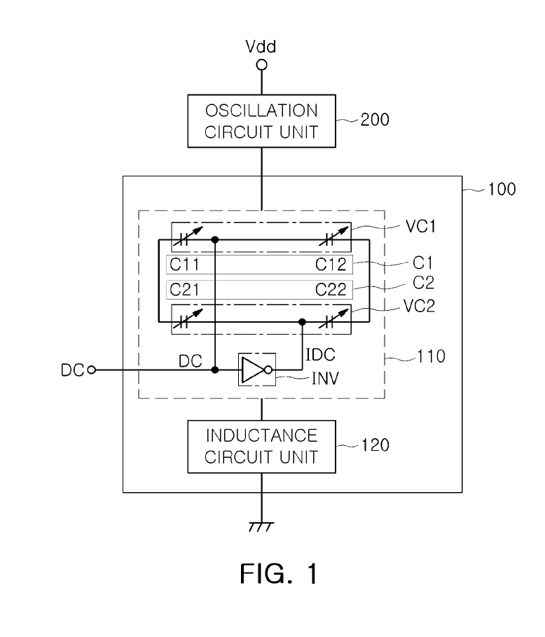

FIG. 1 is a block diagram of a digitally controlled oscillator according to a first embodiment of the present invention.

Referring to FIG. 1, a digitally controlled oscillator according to first embodiment of the present invention may include a resonance circuit unit 100 generating a resonance signal according to varying equivalent capacitance and preset inductance, and an oscillation circuit unit 200 providing negative resistance to the resonance circuit unit 100 and forming oscillation conditions in the resonance circuit unit 100.

Here, the equivalent capacitance may formed in such a manner that a first capacitance C1 varied depending on an input digital control code DC and a second capacitance C2 varied depending on an inverted digital control code IDC generated by inverting the digital control code DC are connected in parallel.

In this case, the resonance circuit unit 100 may provide equivalent capacitance CT (CT=C1+C2) formed by a parallel connection between the first capacitance C1 varied depending on the digital control code DC and the second capacitance C2 varied depending on the inverted digital control code IDC generated by inverting the digital control code DC, and may also provide reset inductance L.

As a result, the resonance circuit unit 100 may generate a resonance signal having a resonance frequency fr, determined according to the equivalent capacitance CT and the inductance L, and the resonance frequency fr is determined as shown in a following equation 1.

$$fr = \frac{1}{2 π \sqrt{L * CT}} \qquad [ Equation 1 ]$$

In addition, the oscillation circuit unit 200 may provide negative resistance to the resonance circuit unit 100 and may form oscillation conditions in the resonance circuit unit 100. Finally, the resonance signal of the resonance circuit unit 100 may be oscillated by the oscillation circuit unit 200.

Moreover, referring to FIG. 1, the resonance circuit unit 100 may include a capacitance circuit unit 110, providing the equivalent capacitance formed by the parallel connection between the first capacitance C1 varied depending on the digital control code DC and the second capacitance C2 varied depending on the inverted digital control code IDC in order to generate the resonance signal, and an inductance circuit unit 120 providing the preset inductance in order to generate the resonance signal.

In this case, when the resonance circuit unit 100 includes the capacitance circuit unit 110 and the inductance circuit unit 120, the capacitance circuit unit 110 may provide the equivalent capacitance formed by the parallel connection between the first capacitance C1 varied depending on the digital control code DC and the second capacitance C2 varied depending on the inverted digital control code IDC in order to generate the resonance signal. Here, when the equivalent capacitance CT is varied, a frequency of the resonance signal may also be varied.

Additionally, the inductance circuit unit 120 may provide the preset inductance L to generate the resonance signal.

In addition, referring to FIG. 1, the capacitance circuit unit 110 may include a first capacitor circuit unit VC1 which provides the first capacitance C1 varied depending on the digital control code DC, an inversion circuit unit INV which provides the inverted digital control code IDC by inverting the digital control code DC, and a second capacitor circuit unit VC2 which is connected to the first capacitor circuit unit VC1 in parallel to provide the second capacitance C2 varied depending on the inverted digital control code IDC.

In this case, the first capacitor circuit unit VC1 may provide the first capacitance C1 varied depending on the digital control code DC1.

The inversion circuit unit INV may be connected to the first capacitor circuit unit VC1 in parallel to provide the inverted digital control code IDC by inverting the digital control code DC.

In addition, the second capacitor circuit unit VC2 may provide the second capacitance C2 varied depending on the inverted digital control code IDC.

Referring to FIG. 1, the first capacitor circuit unit VC1 may include a first capacity element C11 and a second capacity element C12 connected to each other in series to provide the first capacitance C1 determined according to the digital control code DC. The second capacitor circuit unit VC2 may include a third capacity element and a fourth capacity element C21 and C22 connected to each other in series to provide the second capacitance C2 determined according to the inverted digital control code IDC. For example, a varactor diode may be used as the first through the fourth capacity elements C11, C12, C21, and C22. The inversion circuit unit INV may include an inverter inverting the digital control code DC.

In this case, the digital control code DC is supplied to the first and the second capacity elements C11 and C12, and the inverted digital control code IDC is supplied to the third and the fourth capacity elements C21 and C22. When the digital control code DC has a high level, e.g., 1.8V, the inverted digital control code IDC has a low level, e.g., 0V. In contrast, when the digital control code DC has a low level, the inverted digital control code IDC has a high level.

In particular, the first capacitor circuit unit VC1 may be configured to have the first capacitance C1, different from the second capacitance C2 of the second capacitor circuit unit VC2, with respect to the digital control code DC of the same logic level.

For example, the first capacitance provided by the first capacitor circuit unit VC1 and the second capacitance provided by the second capacitor circuit unit VC2 may be preset to be different, with respect to the digital control code having a high level. In addition, the first capacitance provided by the first capacitor circuit unit VC1 and the second capacitance provided by the second capacitor circuit unit VC2 maybe preset to be different, with respect to the digital control code having a low level.

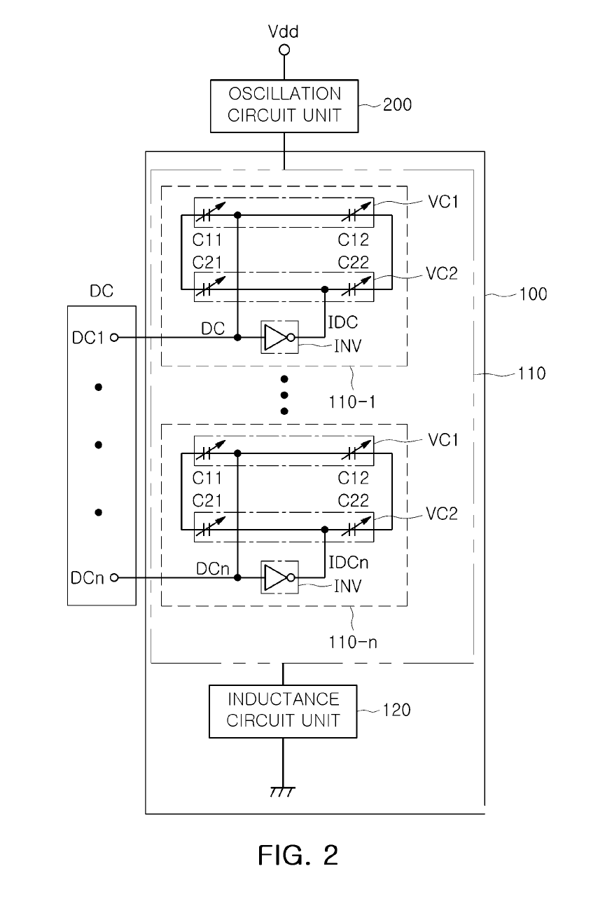

FIG. 2 is a block diagram of a digitally controlled oscillator according to a second embodiment of the present invention.

Referring to FIG. 2, a digitally controlled oscillator according to the second embodiment of the present invention may include the resonance circuit unit 100 generating a resonance signal according to equivalent capacitance varied depending on a digital control code and preset inductance, and the oscillation circuit unit 200 providing negative resistance to the resonance circuit unit 100 and forming oscillation conditions in the resonance circuit unit 100.

The resonance circuit unit 100 may be configured to provide the capacitance circuit unit 110 which includes first to n^{th} variable capacitance circuit units 110-1 to 110-n providing the equivalent capacitor CT, and the inductance L.

Here, respective first through n^{th} variable capacitance circuit units 110-1 to 110-n maybe formed in such a manner that the first capacitance varied depending on the digital control code DC and the second capacitance varied depending on the inverted digital control code IDC generated by inverting the digital control code DC are connected to each other in parallel.

Here, respective first to the n^{th} variable capacitance circuit units 110-1 to 110-n may be configured to provide the equivalent capacitance varied depending on respective first to n^{th} digital control codes DC1 to DCn included in the digital control code DC.

In this case, the resonance circuit unit 100 may generate the resonance signal according to the digital control code. The oscillation circuit unit 200 may provide negative resistance to the resonance circuit unit 100 and form oscillation conditions in the resonance circuit unit 100, such that the resonance signal is oscillated by the oscillation circuit unit 200.

As an example, when the resonance circuit unit 100 includes the capacitance circuit unit 110 and the inductance circuit unit 120, and the capacitance circuit unit 110 includes the first to n^{th} variable capacitance circuit units 110-1 to 110-n, the respective first to the n^{th} variable capacitance circuit units 110-1 to 110-n may provide the equivalent capacitance varied depending on respective first to n^{th} digital control codes DC1 to DCn included in the digital control code DC.

To more detail, respective first to the n^{th} variable capacitance circuit units 110-1 to 110-n may provide the equivalent capacitance CT formed by the parallel connection between the first capacitance varied depending on the digital control code DC and the second capacitance varied depending on the inverted digital control code IDC generated by inverting the digital control code DC.

In addition, the inductance circuit unit 120 may provide preset inductance in advance so as to generate the resonance signal.

Finally, the resonance circuit unit 100 may generate a resonance signal having a resonance frequency f determined according to the equivalent capacitance CT and the inductance L.

In addition, referring to FIG. 2, the first variable capacitance circuit unit 110-1 may include the first capacitor circuit unit VC1 which provides the first capacitance varied depending on the first digital control code DC1, the inversion circuit unit INV which is connected to the first capacitor circuit unit VC1 in parallel to provide a first inverted digital control code IDC1 by inverting the first digital control code DC1, and the second capacitor circuit unit VC2 which provides the second capacitance varied depending on the first inverted digital control code IDC1.

In this case, the first capacitor circuit unit VC1 may provide the first capacitance varied depending on the first digital control code DC1. The inversion circuit unit INV may be connected to the first capacitance circuit unit VC1 in parallel to provide the first inverted digital control code IDC1 by inverting the first digital control code DC1. In addition, the second capacitor circuit unit VC2 may provide the second capacitance varied depending on the first inverted digital control code IDC1.

Referring to FIG. 2, the n^{th} variable capacitance circuit unit 110-n may include the first capacitor circuit unit VC1 which provides the first capacitance varied depending on the n^{th} digital control code DCn, the inversion circuit unit INV which is connected to the first capacitor circuit unit VC1 in parallel to provides an n^{th} inverted digital control code IDCn by inverting the n^{th} digital control code DCn, and the second capacitor circuit unit VC2 which provides the second capacitance varied depending on the n^{th} inverted digital control code IDCn.

In this case, the first capacitor circuit unit VC1 may provide the first capacitance varied depending on the n^{th} digital control code DCn. The inversion circuit unit INV may be connected to the first capacitor circuit unit VC1 to provide the n^{th} inverted digital control code IDCn by inverting the n^{th} digital control code DCn. Additionally, the second capacitor circuit unit VC2 may provide the second capacitance varied depending on the n^{th} inverted digital control code IDCn.

Moreover, referring to FIG. 2, the first capacitor circuit unit VC1 may include the first capacity element C11 and the second capacity element C12 connected to each other in series to provide the first capacitance determined according to the first digital control code DC1. The second capacitor circuit unit VC2 may include the third capacity element and the fourth capacity element C21 and C22 connected to each other in series to provide the second capacitance determined according to the first inverted digital control code IDC1. In addition, the inversion circuit unit INV may include an inverter inverting the first digital control code DC1.

For example, the first and the second capacity elements C11 and C12 and the third and the fourth capacity elements C21 and C22 may be formed of a varactor diode. When the digital control code has a high level, the first and the second capacity elements C11 and C12 and the third and the fourth capacity elements C21 and C22 each have high capacitance and when the digital control code has a low level, the first and the second capacity elements C11 and C12 and the third and the fourth capacity elements C21 and C22 each have low capacitance.

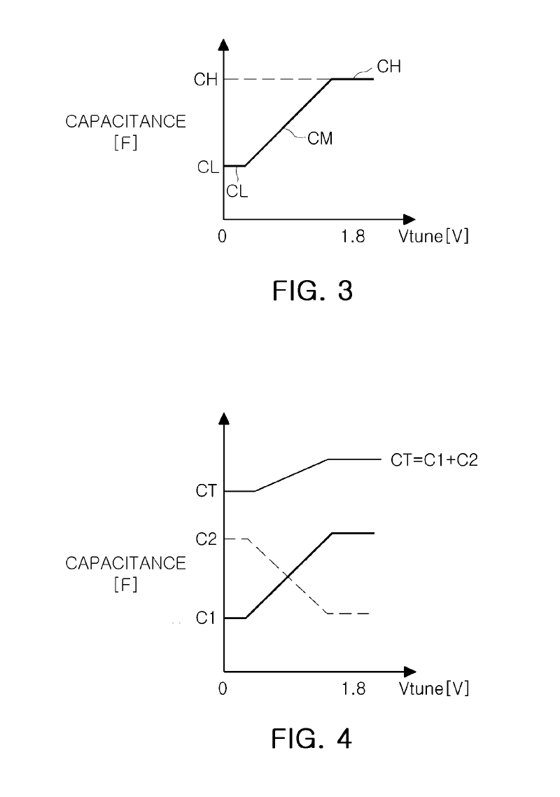

FIG. 3 is a diagram depicting variable capacitance in a digital control mode and an analog control mode, according to an embodiment of the present invention.

Referring to FIG. 3, the first capacitor circuit unit VC1 or the second capacitor circuit unit VC2 is characterized in that low capacitance CL is provided when the digital control code has a low level and high capacitance CH is provided when the digital control code has a high level.

In the analog control mode, the first capacitor circuit unit VC1 and the second capacitor circuit unit VC2 may be controlled to have linearly-varied capacitance CM between the low capacitance CL and the high capacitance CH; however, in a digital control mode, the first capacitor circuit unit VC1 and the second capacitor circuit unit VC2 maybe controlled to only have either low capacitance CL or high capacitance CH.

However, when the first capacitor circuit unit VC1 and the second capacitor circuit unit VC2 according to the embodiment of the present invention are connected to each other in parallel and are controlled by the digital control code DC and the inverted digital control code IDC, the first capacitor circuit unit VC1 and the second capacitor circuit unit VC2 may be controlled by capacitance between the low capacitance CL and the high capacitance CH.

FIG. 4 is a conceptual graph depicting variable capacitance of a capacitance circuit unit according to an embodiment of the present invention.

Referring to FIGS. 2 through 4, the first and the second capacity elements C11 and C12 are supplied with the digital control code DC, and the third and the fourth capacity elements C21 and C22 are supplied with the inverted digital control code IDC. When the digital control code DC has a high level, e.g., 1.8V, the inverted digital control code IDC has a low level, e.g., 0V, and on the other hand, when the digital control code DC has a low level, the inverted digital control code IDC has a high level.

In particular, the first capacitor circuit unit VC1 may be formed to have the first capacitance C1, different from the second capacitance C2 of the second capacitor circuit unit VC2, with respect to the digital control code DC having the same logic level.

For example, the first capacitance provided by the first capacitor circuit unit VC1 and the second capacitance provided by the second capacitor circuit unit VC2 may be preset to be different, with respect to the digital control code having a high level. In addition, the first capacitance provided by the first capacitor circuit unit VC1 and the second capacitance provided by the second capacitor circuit unit VC2 may be preset to be different, with respect to the digital control code having a low level.

Accordingly, the equivalent capacitance CT, formed by summing the first capacitance C1 of the first capacitor circuit unit VC1 and the second capacitance C2 of the second capacitor circuit unit VC2 in parallel may be different when the digital control code has a high level or a low level, respectively.

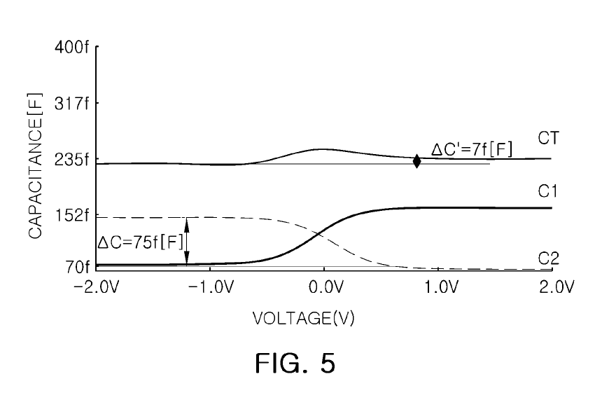

FIG. 5 is a graph of variable capacitance of a capacitance circuit unit according to the first embodiment of the present invention.

Referring to FIGS. 1 and 5, when the capacitance circuit unit 110 according to an embodiment of the present invention includes a single first variable capacitance circuit unit 110-1, the first capacitor circuit unit VC1 of the first variable capacitance circuit unit 110-1 may provide the first capacitance C1 determined according to the first digital control code DC1, and the second capacitor circuit unit VC2 may provide the second capacitance C2 determined according to the first inverted digital control code IDC1. Consequently, the equivalent capacitance CT determined by the first capacitance C1 and the second capacitance C2 may be provided.

In terms of a capacitance discrepancy LC in one of the first capacitor circuit unit VC1 and the second capacitor circuit unit VC2 in FIG. 5, the discrepancy ° C. between capacitance in the case in which the digital control code has a high level and capacitance in the case in which the digital control code has a low level is 75 fF.

On the other hand, when the first capacitor circuit unit VC1 and the second capacitor circuit unit VC2 are connected to each other in parallel and controlled by the digital control code and the inverted digital control code, respectively, according to the embodiment of the present invention, the discrepancy ° C. between capacitance in the case in which the digital control code has a high level and capacitance in the case in which the digital control code has a low level is 7 fF.

That is, according to the embodiment of the present invention, capacitance may be more accurately controlled through the digital control code.

As set forth above, according to the embodiments of the present invention, there is provided a digitally controlled oscillator having improved linearity, capable of being applied to a communications system and linearly controlling an oscillation frequency according to a digital control code.

While the present invention has been shown and described in connection with the embodiments, it will be apparent to those skilled in the art that modifications and variations can be made without departing from the spirit and scope of the invention as defined by the appended claims.

What is claimed is:

1. A digitally controlled oscillator, comprising:
a resonance circuit unit generating a resonance signal according to equivalent capacitance varied depending on a digital control code and preset inductance; and
an oscillation circuit unit providing negative resistance to the resonance circuit unit and forming oscillation conditions in the resonance circuit unit,
wherein the equivalent capacitance is a parallel summed capacitance of a first capacitance varied depending on the digital control code and a second capacitance varied depending on an inverted digital control code generated by inverting the digital control code.

2. The digitally controlled oscillator of claim 1, wherein the resonance circuit unit includes:
a capacitance circuit unit providing the equivalent capacitance in order to generate the resonance signal; and
an inductance circuit unit providing the preset inductance in order to generate the resonance signal.

3. The digitally controlled oscillator of claim 2, wherein the capacitance circuit unit includes:
a first capacitor circuit unit providing the first capacitance varied depending on the digital control code;
an inversion circuit unit providing the inverted digital control code by inverting the digital control code; and
a second capacitor circuit unit connected to the first capacitor circuit unit in parallel to provide the second capacitance varied depending on the inverted digital control code.

4. The digitally-controlled oscillator of claim 3, wherein the first capacitor circuit unit includes a first capacity element and a second capacity element connected to each other in series to provide the first capacitance determined according to the digital control code.

5. The digitally-controlled oscillator of claim 4, wherein the second capacitor circuit unit includes a third capacity element and a fourth capacity element connected to each other in series to provide the second capacitance determined according to the inverted digital control code.

6. The digitally controlled oscillator of claim 5, wherein the inversion circuit unit includes an inverter inverting the digital control code.

7. The digitally controlled oscillator of claim 5, wherein the first capacitor circuit unit has the first capacitance different from the second capacitance of the second capacitor circuit unit, with respect to the digital control code having the same logic level.

8. A digitally controlled oscillator, comprising:
a resonance circuit unit generating a resonance signal according to equivalent capacitance varied depending on a digital control code and preset inductance; and
an oscillation circuit unit providing negative resistance to the resonance circuit unit and forming oscillation conditions in the resonance circuit unit,
wherein the resonance circuit unit includes: a capacitance circuit unit including first through n^{th} variable capacitance circuit units providing the equivalent capacitance; and an inductance circuit unit providing the inductance,
the equivalent capacitance of the first through n^{th} variable capacitance circuit units being a parallel summed capacitance of the first capacitance varied depending on the digital control code and the second capacitance varied depending on an inverted digital control code generated by inverting the digital control code.

9. The digitally controlled oscillator of claim 8, wherein respective first through n^{th} variable capacitance circuit units provides equivalent capacitance varied depending on respective first through n^{th} digital control codes included in the digital control code.

10. The digitally controlled oscillator of claim 9, wherein the first variable capacitance circuit unit includes:
a first capacitor circuit unit providing the first capacitance varied depending on the first digital control code;
an inversion circuit unit providing the first inverted digital control code by inverting the first digital control code; and
a second capacitor circuit unit connected to the first capacitor circuit unit in parallel to provide the second capacitance varied depending on the first inverted digital control code.

11. The digitally controlled oscillator of claim 10, wherein the first capacitor circuit unit includes a first capacity element and a second capacity element connected to each other in series to provide the first capacitance determined according to the first digital control code.

12. The digitally controlled oscillator of claim 11, wherein the second capacitor circuit unit includes a third capacity element and a fourth capacity element connected to each other in series to provide the second capacitance determined according to the first inverted digital control code.

13. The digitally controlled oscillator of claim 12, wherein the inversion circuit unit includes an inverter inverting the first digital control code.

14. The digitally controlled oscillator of claim 13, wherein the first capacitor circuit unit has the first capacitance different from the second capacitance of the second capacitor circuit unit, with respect to the first digital control code having the same logic level.

15. The digitally controlled oscillator of claim 10, wherein the n^{th} variable capacitance circuit unit includes:
a first capacitor circuit unit providing the first capacitance varied depending on the n^{th} digital control code;
an inversion circuit unit providing the n^{th} inverted digital control code by inverting the n^{th} digital control code; and
a second capacitor circuit unit connected to the first capacitor circuit unit in parallel to provide the second capacitance varied depending on the n^{th} inverted digital control code.

16. The digitally controlled oscillator of claim 15, wherein the first capacitor circuit unit includes a first capacity element and a second capacity element connected to each other in series to provide the first capacitance determined according to the n^{th} digital control code.

17. The digitally controlled oscillator of claim 16, wherien the second capacitor circuit unit includes a third capacity element and a fourth capacity element connected to each other in series to provide the second capacitance determined according to the n^{th} inverted digital control code.

18. The digitally controlled oscillator of claim 17, wherein the inversion circuit unit includes an inverter inverting the n^{th} digital control code.

19. The digitally controlled oscillator of claim 17, wherein the first capacitor circuit unit has the first capacitance, different from the second capacitance of the second capacitor circuit unit, with respect to the n^{th} digital control code having the same logic level.
